(19) United States
(12) Patent Application Publication
(10) Pub. No.: US 2014/0070679 A1
(43) Pub. Date: Mar. 13, 2014

(54) POWER DISTRIBUTION UNIT AND SERVER CABINET WITH THE SAME

(71) Applicant: AN-GANG LIANG, Shenzhen City (CN)

(72) Inventor: AN-GANG LIANG, Shenzhen City (CN)

(21) Appl. No.: 13/631,777

(22) Filed: Sep. 28, 2012

(30) Foreign Application Priority Data
Sep. 7, 2012 (CN) 2012103285507

(51) Int. Cl. H05K 5/02; H05K 7/18

(52) U.S. Cl. 312/223.1; 211/26

(57) ABSTRACT

A server cabinet includes a rack and a power distribution unit (PDU). The rack includes a side plate and a mounting bracket extending from the side plate. An engaging portion is formed on the mounting bracket. The engaging portion includes a sidewall. The sidewall defines a notch. A mounting portion is formed on the side plate. The mounting portion and the side plate bound a through hole. The PDU includes a main body and a position bracket. A block protrudes from the main body. The block includes a neck for engaging in the notch, and a head for abutting the sidewall. The position bracket is fastened to the main body and includes a position portion. A stop tab extends from the position portion. The position portion deformably extends through the through hole to allow the stop tab to be blocked by a bottom of the mounting portion.

### BACKGROUND

1. Technical Field

The present disclosure relates to a server cabinet having a power distribution unit (PDU).

2. Description of Related Art

A PDU of a server cabinet is generally screwed to a side of the rack of the cabinet. Mounting the PDU with screws requires the use of a tool, such as a screwdriver, which is inconvenient.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an assembled view of an exemplary embodiment of a server cabinet, wherein the cabinet includes a power distribution unit (PDU) with a main body.

FIG. 2 is an enlarged view of a circled portion II of FIG. 1.

FIG. 3 is an exploded view of FIG. 1.

FIG. 4 is an enlarged view of a circled portion IV of FIG. 3.

FIG. 5 is a part of an inverted view of the main body of FIG. 3.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

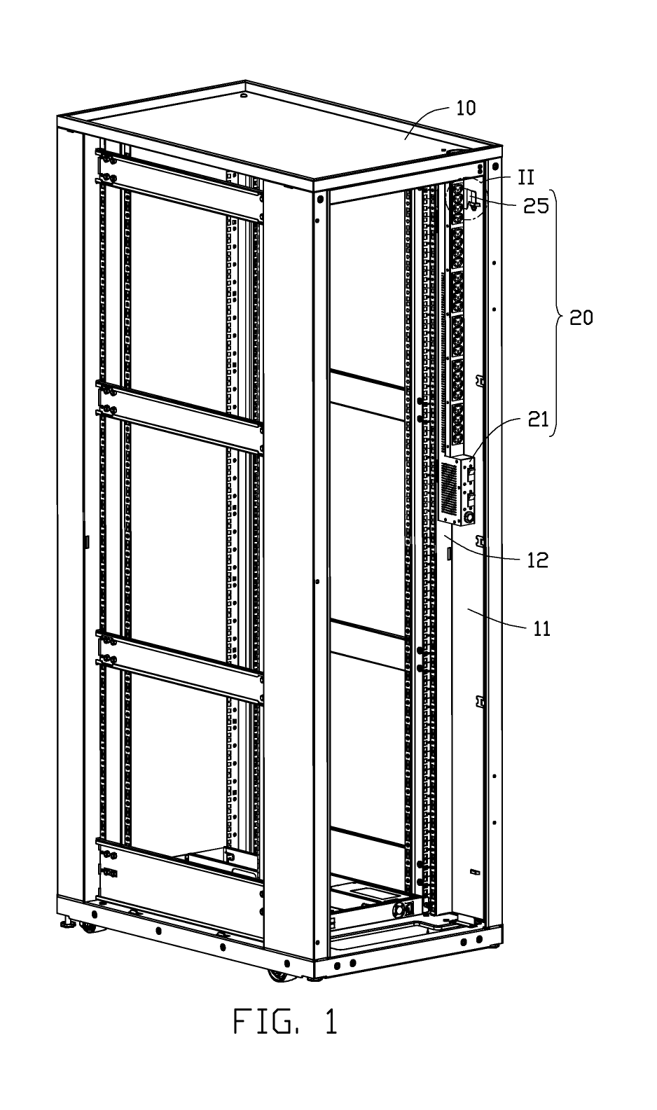

FIG. 1 shows an exemplary embodiment of a server cabinet including a rack 10 and a power distribution unit (PDU) 20. The PDU 20 includes a main body 21 and a position bracket 25.

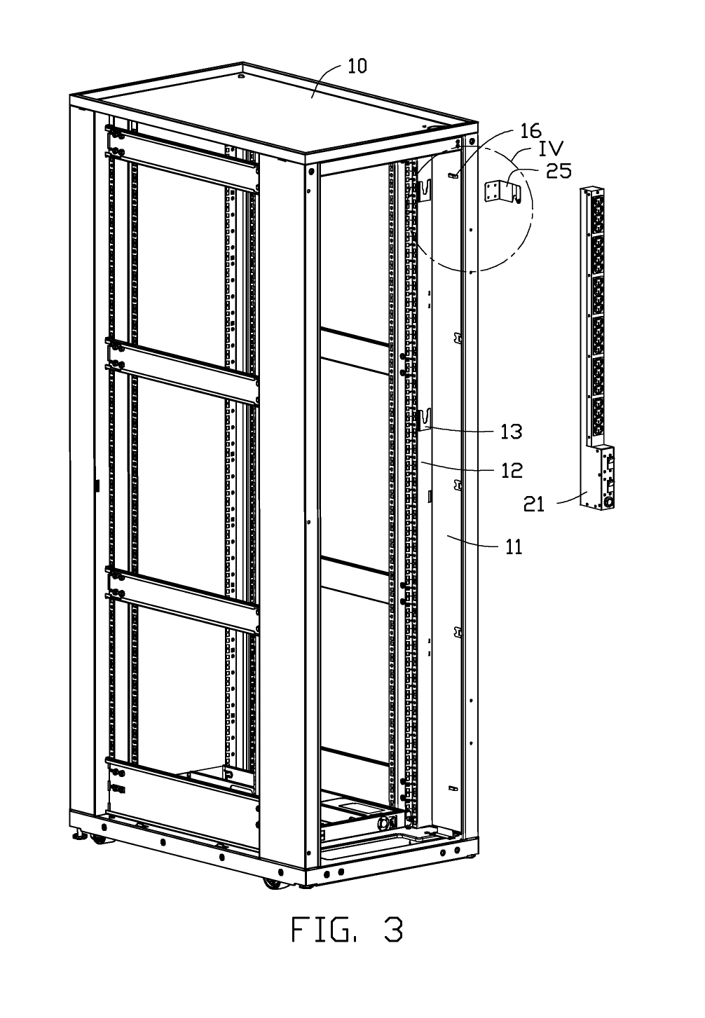

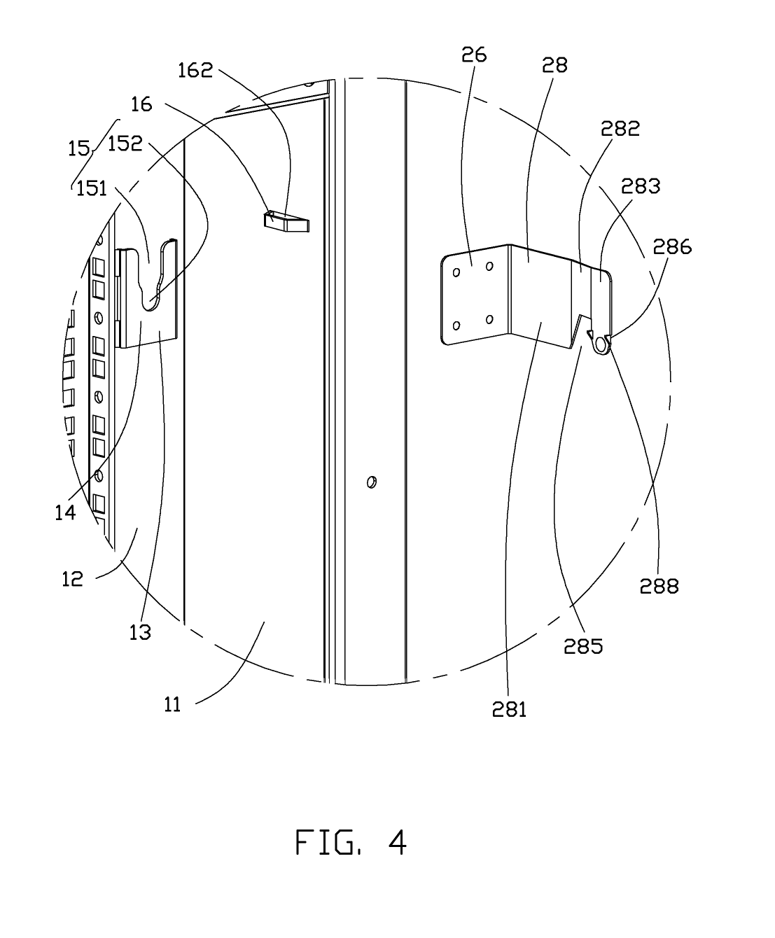

FIGS. 3 and 4 show the rack 10 including a side plate 11. A mounting bracket 12 perpendicularly extends from an inner side of the side plate 11. Two engaging portions 13 are formed on the mounting bracket 12, arranged one above the other. Each engaging portion 13 includes a sidewall 14 spaced from and parallel to the mounting bracket 12. The sidewall 14 defines a notch 15 extending through a top of the sidewall 14. The notch 15 includes an access 151 extending through the top of the sidewall 14, and a hooking slot 152 communicating with a bottom of the access 151. The width of the hooking slot 152 is less than the width of the access 151. A bridge-shaped mounting portion 16 is formed on the inner side of the side plate 11, beside the mounting bracket 12. The mounting portion 16 and the side plate 11 bound a through hole 162.

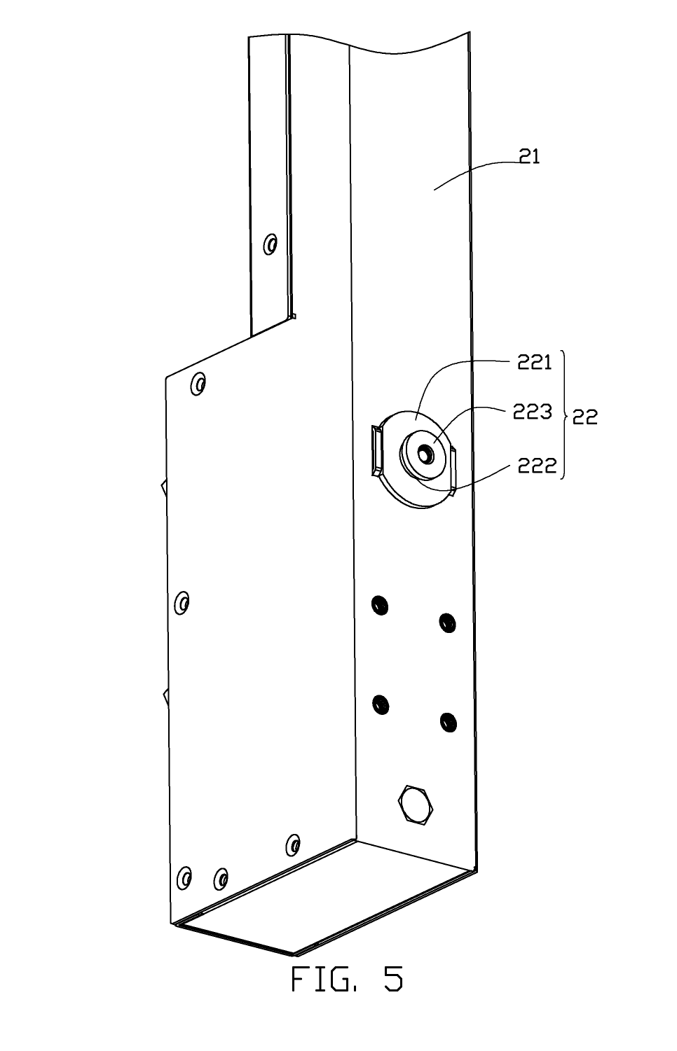

FIG. 5 shows two blocks 22 respectively protruding from upper and lower portions of the main body 21. Each block 22 includes a connection portion 221 protruding from the main body 21, a columnar neck 222 protruding from the connection portion 221, and a columnar head 223 formed at a distal end of the neck 222. The head 223 is coaxial with the neck 222 and has a greater diameter than the diameter of the neck 222. The diameter of the head 223 is greater than the width of the access 151. The diameter of the neck 222 is less than the width of the hooking slot 152.

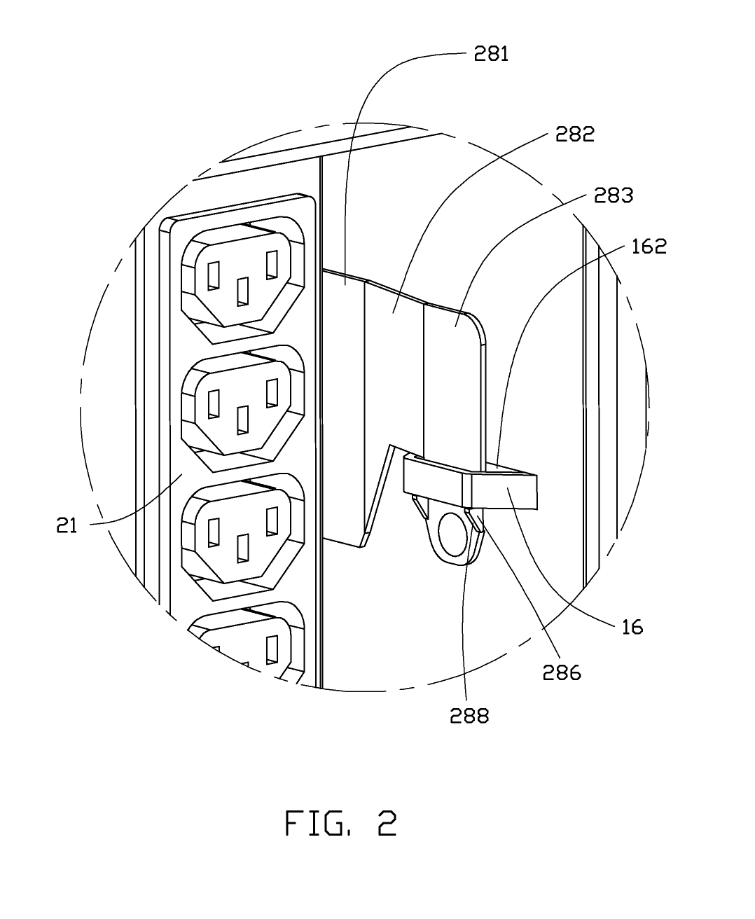

FIGS. 2 and 4 show the position bracket 25 including a base plate 26 and a position portion 28. The position portion 28 includes an extension plate 281 extending forward from a side of the base plate 26, a connection plate 282 slantingly extending forward and inward from a front side of the extension plate 281, and an engaging plate 283 extending forward from a front side of the connection plate 282. An opening 285 is defined in a bottom of the connection plate 282 and located at a lower side portion of the engaging plate 283, to allow the lower portion of the engaging plate 283 to extend through the through hole 162. Two stop tabs 286 extend inward from opposite sides of the lower portion of the engaging plate 283. A slanting guiding surface 288 is formed on each stop tab 286.

FIGS. 1 and 2 show in assembly, the base plate 26 is fastened to the rear side of the main body 21 by screws. The position portion 28 is located between the main body 21 and the side plate 11. The main body 21 with the position bracket 25 is manipulated down. The necks 222 respectively extend through the accesses 151 and engage in the hooking slots 152. The heads 223 abut inner sides of the sidewalls 14. The connection portions 221 abut outer sides of the sidewalls 14. At the same time, guided by the guiding surfaces 288, the stop tabs 286 with the engaging plate 283 is moved toward the side plate 11 after the stop tabs 286 abuts the mounting portion 16, deforming the connection plate 282 toward the side plate 11. When the stop tabs 286 extend through the through holes 162, the connection plate 282 is restored, and the stop tabs 286 are restored to be blocked by a bottom of the mounting portion 16.

In a second embodiment, the extension plate 281, the connection plate 282 and the engaging plate 283 are coplanar.

In a third embodiment, the opening 285 is omitted, the engaging plate 283 extends down out of a bottom of the position portion 28, the stop tabs 286 are located below the extension plate 281 and the connection plate 282.

Even though numerous characteristics and advantages of the embodiments have been set forth in the foregoing description, together with details of the structure and the functions of the embodiments, the disclosure is illustrative only, and changes may be made in details, especially in the matters of shape, size, and arrangement of parts within the principles of the embodiments to the full extent indicated by the broad general meaning of the terms in which the appended claims are expressed.

What is claimed is:

1. A power distribution unit (PDU), comprising:
a main body comprising:
a block comprising a neck and a head formed at a distal end of the neck, a size of a cross-section of the head being larger than a size of a cross-section of the neck; and
a position bracket comprising a deformable position portion located at a side of the main body and a stop tab extending from the position portion.

2. The PDU of claim 1, wherein the position bracket comprises a base plate fastened to the main body, the position portion extends from a side of the base plate.

3. The PDU of claim 2, wherein the position portion comprises an extension plate extending forward from the side of the base plate, a connection plate slantingly extending forward and inward from a front side of the extension plate, and an engaging plate extending forward from a front side of the connection plate, the stop tab extends inward from a lower portion of the engaging plate.

4. The PDU of claim 3, wherein a lower portion of the connection plate defines an opening extending through a bottom of the connection plate and located beside the engaging plate.

5. The PDU of claim 1, wherein the neck and the head are columnar and coaxial with each other, the diameter of the head is greater than that of the neck.

6. The PDU of claim 1, wherein the block protrudes from the maim body and further comprises a connection portion protruding from the main body, the neck protrudes from a side of the connection portion away from the main body.

7. A server cabinet, comprising:
a rack comprising a side plate and a mounting bracket perpendicularly extending from the side plate, an engaging portion formed on the mounting bracket, the engaging portion comprising a sidewall spaced from and parallel to the mounting bracket, the sidewall defining a notch extending through a top of the sidewall, a mounting portion formed on the side plate, the mounting portion and the side plate bounding a through hole; and
a power distribution unit (PDU) comprising a main body, the main body comprising a position bracket and a block, the block comprising a neck for engaging in the notch, and a head formed at a distal end of the neck for abutting an inner side of the sidewall, the position bracket comprising a deformable position portion located between the main body and the side plate, a stop tab extending from the position portion, the position portion deformably extending through the through hole to allow the stop tab to be blocked by a bottom of the mounting portion.

8. The server cabinet of claim 7, wherein the notch comprises an access extending through the top of the sidewall, and a hooking slot communicating with a bottom of the access, the width of the hooking slot is less than that of the access, the neck extends through the access and engages in the hooking slot.

9. The server cabinet of claim 7, wherein the neck and the head are columnar and coaxial with each other, the diameter of the head is greater than that of the neck.

10. The server cabinet of claim 7, wherein the block protrudes from the maim body and further comprises a connection portion protruding from the main body, the neck protrudes from a side of the connection portion away from the main body, the connection portion abuts an outer side of the sidewall.

11. The server cabinet of claim 7, wherein the position bracket comprises a base plate fastened to the main body, the position portion extends from a side of the base plate.

12. The server cabinet of claim 11, wherein the position portion comprises an extension plate extending forward from the side of the base plate, a connection plate slantingly extending forward and inward from a front side of the extension plate, and an engaging plate extending forward from a front side of the connection plate, the stop tab extends inward from a lower portion of the engaging plate, the connection plate defines an opening extending through a bottom of the connection plate and located beside the engaging plate, the lower portion of the engaging plate deformably extending through the through hole, to allow the stop tab to be blocked by the bottom of the mounting portion.
